(19) United States
(12) Patent Application Publication
(10) Pub. No.: US 2026/0371587 A1
(43) Pub. Date: Nov. 19, 2026

(54) SEMICONDUCTOR MEMORY DEVICE AND METHOD OF MANUFACTURING A SEMICONDUCTOR MEMORY DEVICE

(71) Applicant: SK hynix Inc., Icheon-si Gyeonggi-do (KR)

(72) Inventor: Jeong Sang KANG, Icheon-si Gyeonggi-do (KR)

(73) Assignee: SK hynix Inc., Icheon-si Gyeonggi-do (KR)

(21) Appl. No.: 19/431,498

(22) Filed: Dec. 23, 2025

(30) Foreign Application Priority Data
May 13, 2025 (KR) 10-2025-0061943

(51) Int. Cl. H10B 43/27; G11C 16/04; H10B 41/27; H10B 41/35; H10B 41/41; H10B 41/50; H10B 43/35; H10B 43/40; H10B 43/50; H10D 1/00; H10D 1/68; H10D 30/01; H10D 30/68; H10D 30/69; H10D 62/83; H10P 10/00; H10W 80/00

(52) U.S. Cl. CPC H10B 43/27; G11C 16/0483; H10B 41/27; H10B 41/35; H10B 41/41; H10B 41/50; H10B 43/35; H10B 43/40; H10B 43/50; H10D 1/041; H10D 1/692; H10D 30/0411; H10D 30/0413; H10D 30/689; H10D 30/693; H10D 62/83; H10P 10/128; H10W 80/312

(57) ABSTRACT

A semiconductor memory device and a method of manufacturing the semiconductor memory device are included. The semiconductor memory device includes a gate stack formed within a cell region of the semiconductor memory device, a dummy stack formed within a peripheral circuit region of the semiconductor memory device and separated from the cell region, a source layer formed on the gate stack, a capacitor including a first electrode, a dielectric layer, and a second electrode formed on the dummy stack, and a plurality of channel structures extending through the dummy stack and protruding into the source layer, wherein the source layer is formed at a same level as the first electrode.

### CROSS REFERENCE TO RELATED APPLICATION

The present application claims priority under 35 U.S.C. §119(a) to Korean patent application number 10-2025-0061943 filed on May 13, 2025, in the Korean Intellectual Property Office, the entire contents of which application is incorporated herein by reference.

### BACKGROUND

### 1. Technical Field

The present disclosure relates to an electronic device, including but not limited to a semiconductor memory device having a vertical channel structure and a method of manufacturing a semiconductor memory device.

### 2. Related Art

Recently, the paradigm of the computer environment has shifted to ubiquitous computing, which enables computer systems to be used anytime and anywhere. A surge in the use of portable electronic devices such as cell phones, digital cameras, and laptop computers has resulted. These portable electronic devices typically utilize memory systems using semiconductor memory devices, such as data storage devices. Data storage devices are used as primary or secondary memory devices in portable electronic devices.

A data storage system using a semiconductor memory device has advantages of excellent stability and durability due to the absence of a mechanical driving part as well as extremely fast information access speed and low power consumption. As examples of the memory system with these advantages, data storage devices include Universal Serial Bus (USB) memory devices, memory cards with various interfaces, and solid state drives (SSDs).

Semiconductor memory devices are characterized as volatile memory devices or non-volatile memory devices.

Non-volatile memory devices have relatively slow write and read speeds, but retain stored data when the power supply is interrupted or discontinued. Non-volatile memory devices are used to store data to be retained regardless of whether the power is supplied or not. Non-volatile memory devices include Read Only Memory (ROM), Mask ROM (MROM), Programmable ROM (PROM), Erasable Programmable ROM (EPROM), Electrically Erasable Programmable ROM (EEPROM), Flash memory, Phase Change Random Access Memory (PRAM), Magnetic RAM (MRAM), Resistive RAM (RRAM), Ferroelectric RAM (FRAM), and the like. Flash memory is categorized as NOR type or NAND type.

### SUMMARY

According to an embodiment, a semiconductor memory device may include a gate stack formed within a cell region, a dummy stack formed within a peripheral circuit region of the semiconductor memory device and separated from the cell region, a source layer formed on the gate stack, a capacitor including a first electrode, a dielectric layer, and a second electrode formed on the dummy stack, and a plurality of channel structures extending through the dummy stack and protruding into the source layer, wherein the source layer is formed at a same level as the first electrode.

According to an embodiment, a semiconductor memory device may include a gate stack formed within a cell region of the semiconductor memory device, a dummy stack formed within a peripheral circuit region separated from the cell region, a source layer formed on the gate stack, a capacitor including a first electrode, a dielectric layer, and a second electrode formed on the dummy stack, a plurality of channel structures extending through the dummy stack and protruding into the source layer, a first connecting structure including a first bonding metal having a surface near the gate stack, a second connecting structure including a second bonding metal in contact with the first bonding metal of the first connecting structure, and a Complementary Metal-Oxide Semiconductor (CMOS) circuit structure coupled to the second connecting structure and including a plurality of transistors.

According to an embodiment, a method of manufacturing a semiconductor memory device may include: forming a stack including interlayer insulating layers alternatively stacked with sacrificial layers in a first direction on a first substrate including a cell region and a peripheral circuit region, and a plurality of channel structures extending through the stack within the cell region, forming a gate stack including the interlayer insulating layers alternatively stacked with conductive layers within the cell region by replacing the sacrificial layers within the cell region with conductive layers, and forming a dummy stack by alternately stacking the interlayer insulating layers with the sacrificial layers within the peripheral circuit region, forming a bit line coupled to each of the plurality of channel structures, removing the first substrate to expose the plurality of channel structures, forming a conductive layer on the gate stack and the dummy stack exposed by removing the first substrate, and forming a source layer connected to the plurality of channel structures on the gate stack and a first electrode on the dummy stack by patterning the conductive layer, and forming a capacitor by consecutively forming a dielectric layer and a second electrode on the first electrode.

### BRIEF DESCRIPTION OF THE DRAWINGS

FIG. 1 is a block diagram illustrating a semiconductor memory device according to an embodiment of the present disclosure;

FIG. 2 is a circuit view illustrating a memory cell array of FIG. 1;

FIG. 3 is a cross-sectional view of a semiconductor memory device according to an embodiment of the present disclosure;

FIGS. 4A-4G, 5, 6, and 7A-7C are cross-sectional views of a semiconductor memory device formed utilizing a method of manufacturing a semiconductor memory device according to an embodiment of the present disclosure;

FIG. 8 is a block diagram illustrating a configuration of a memory system according to an embodiment of the present disclosure; and

FIG. 9 is a block diagram illustrating a configuration of a computing system according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

When one element is identified as “connected” or “coupled” to another element, the elements may be connected or coupled directly or through at least one intervening element between the elements. When two elements are identified as “directly connected” or “directly coupled,” one element is directly connected or directly coupled to the other element without an intervening element between the two elements.

Terms such as “vertical,” “horizontal,” “top,” “bottom,” “above,” “under,” “beneath,” “overlap,” “on,” “side,” “upper,” “uppermost,” “lower,” “lowermost,” “high,” “low,” “row,” “level,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

Terms such as “first” and “second” are used to distinguish between various elements and do not imply size, order, priority, quantity, or importance of the elements. For example, a first element may be referred to as a second element in one example, and the second element may be referred to as a first element in another example.

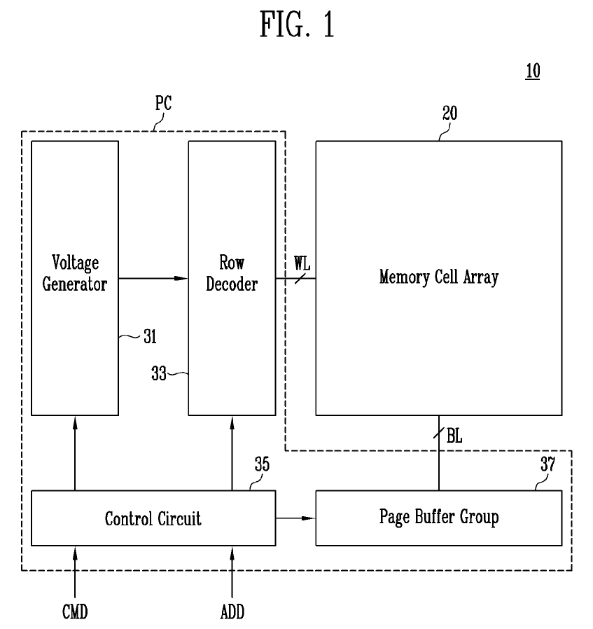

FIG. 1 is a block diagram illustrating a semiconductor memory device 10 according to an embodiment of the present disclosure.

Referring to FIG. 1, the semiconductor memory device 10 includes a peripheral circuit PC and a memory cell array 20.

The peripheral circuit PC is configured to control a program operation that stores data in the memory cell array 20, a read operation that outputs data stored in the memory cell array 20, and an erase operation that erases data stored in the memory cell array 20.

In an embodiment, the peripheral circuit PC includes a voltage generator 31, a row decoder 33, a control circuit 35, and a page buffer group 37.

The memory cell array 20 includes a plurality of memory blocks. The memory cell array 20 is coupled to the row decoder 33 via word lines WL and is coupled to the page buffer group 37 via bit lines BL.

The control circuit 35 controls the voltage generator 31, the row decoder 33, and the page buffer group 37 in response to commands CMD and addresses ADD.

The voltage generator 31 generates various operation voltages, such as an erase voltage, a ground voltage, a program voltage, a verify voltage, a pass voltage, and a read voltage used for a program operation, a read operation, and an erase operation in response to control of the control circuit 35.

The row decoder 33 selects a memory block in response to control from the control circuit 35. The row decoder 33 is configured to apply the operation voltages to the word lines WL coupled to the selected memory block.

The page buffer group 37 is coupled to the memory cell array 20 via the bit lines BL. The page buffer group 37 temporarily stores data received from an input/output circuit (not shown) during a program operation in response to control of the control circuit 35. The page buffer group 37 senses a voltage or current of the bit lines BL during a read operation or a verify operation in response to control of the control circuit 35. The page buffer group 37 selects the bit lines BL in response to control of the control circuit 35.

Structurally, the memory cell array 20 may at least partially overlap the peripheral circuit PC. For example, the peripheral circuitry PC may overlap with an upper or lower section of the memory cell array 20. The memory cell array 20 may be arranged nearby or adjacent to the peripheral circuit PC.

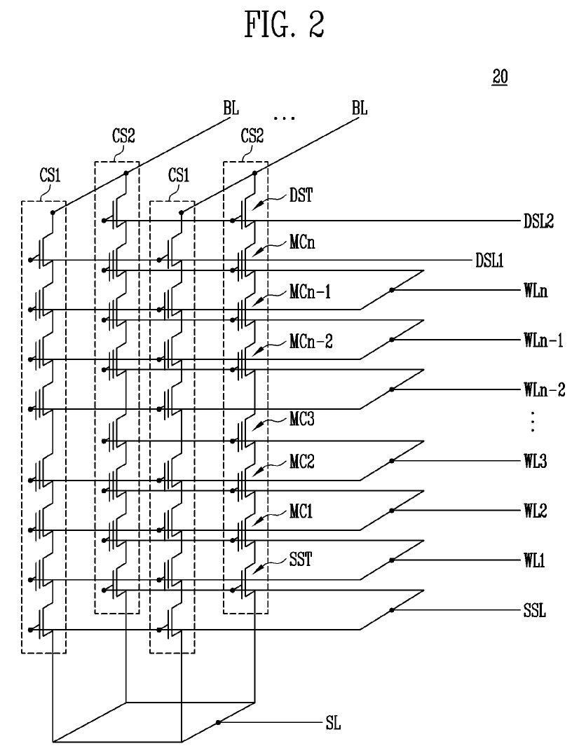

FIG. 2 is a circuit view illustrating the memory cell array 20 of FIG. 1.

Referring to FIG. 2, the memory cell array 20 includes a plurality of cell strings CS1 and CS2 coupled between a source line SL and the plurality of bit lines BL. The plurality of cell strings CS1 and CS2 are coupled in common to a plurality of word lines WL1 to WLn.

Each of the plurality of cell strings CS1 and CS2 includes at least one source select transistor SST coupled to the source line SL, at least one drain select transistor DST coupled to the bit line BL, and a plurality of memory cells MC1 to MCn coupled in series between the source select transistor SST and the drain select transistor DST.

Gates of the plurality of memory cells MC1 to MCn are coupled to the plurality of word lines WL1 to WLn spaced apart and stacked. The plurality of word lines WL1 to WLn are arranged between a source select line SSL and two or more drain select lines DSL1 and DSL2. The two or more drain select lines DSL1 and DSL2 are spaced apart at a same level or in the same plane.

A gate of the source select transistor SST is coupled to the source select line SSL. A gate of the drain select transistor DST is coupled to a drain select line DSL1 or DSL2 corresponding to the gate of the drain select transistor DST.

The source line SL is coupled to a source of the source select transistor SST. A drain of the drain select transistor DST is coupled to a bit line corresponding to the drain of the drain select transistor DST.

The plurality of cell strings CS1 and CS2 are divided into string groups coupled to the two or more drain select lines DSL1 and DSL2. Cell strings coupled to the same word line and the same bit line are independently controlled by different drain select lines. Cell strings coupled to the same drain select line are independently controlled by different bit lines.

In an embodiment, the two or more drain select lines DSL1 and DSL2 include a first drain select line DSL1 and a second drain select line DSL2. The plurality of cell strings CS1 and CS2 include a first cell string CS1 of a first string group coupled to the first drain select line DSL1 and a second cell string CS2 of a second string group coupled to the second drain select line DSL2.

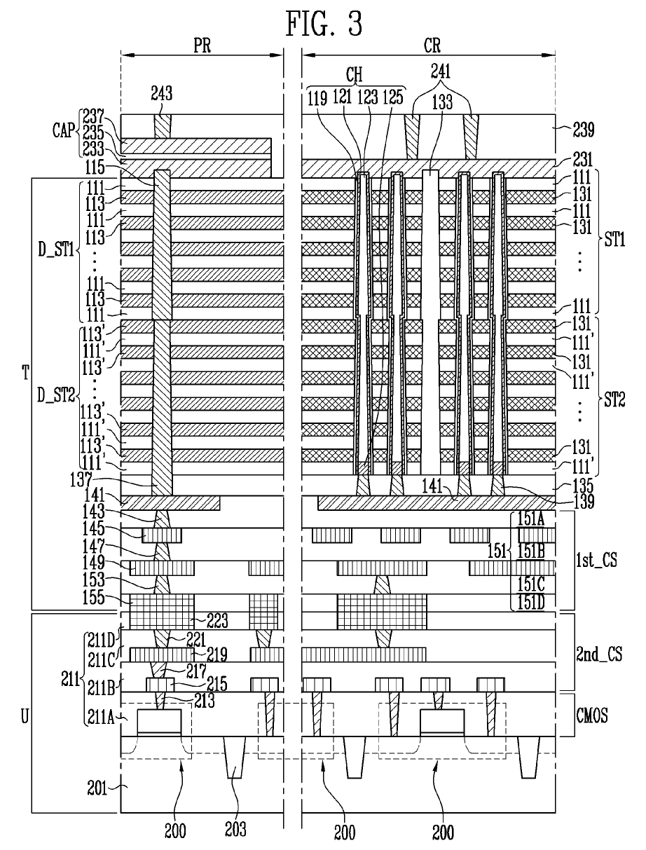

FIG. 3 is a cross-sectional view of a semiconductor memory device according to an embodiment of the present disclosure.

Referring to FIG. 3, the semiconductor memory device is arranged by bonding a lower structure U to an upper structure T.

A memory cell array includes the lower structure U bonded to the upper structure T.

The upper structure T includes a first gate stack ST1 and a second gate stack ST2 stacked in a vertical direction within a cell region CR of the memory device 10, channel structures CH, and insulating patterns 133 vertically extending through the first gate stack ST1 and the second gate stack ST2, a lower wiring 141 arranged under the second gate stack ST2, and a first connecting structure 1st_CS.

At the border of the first gate stack ST1 and the second gate stack ST2, a width of the insulating pattern 133 may vary. For example, the width of the insulating pattern 133 at or above a lowermost surface of the first gate stack ST1 is greater than the width of the insulating pattern 133 at or below an uppermost surface of the second gate stack ST2.

In the cell region CR, the first gate stack ST1 and the second gate stack ST2 include interlayer insulating layers 111 and 111’ alternatively stacked with conductive patterns 131 in a vertical direction. Each of the conductive patterns 131 may include various conductive materials, such as a doped silicon layer, a metal layer, a metal silicide layer, and a barrier layer and may include two or more types of conductive materials. For example, each of the conductive layers 131 may include tungsten and a titanium nitride (TiN) layer covering the surface of the tungsten. Tungsten is a low-resistance metal that may lower the resistance of the conductive patterns 131. The titanium nitride (TiN) layer is a barrier layer that may prevent direct contact between the tungsten and the interlayer insulating layers 111 and 111’.

Among the conductive patterns 131, a conductive pattern closest to the lower wiring 141 functions as the drain select line DSL as shown in FIG. 2. In an embodiment, two or more conductive patterns closest to the lower wiring 141 and stacked consecutively may function as drain select lines. Among the conductive patterns 131, a conductive pattern closest to a source layer 231 functions as the source select line SSL in FIG. 2. In an embodiment, two or more conductive patterns closest to the source layer 231 and stacked consecutively may function as source select lines. Conductive patterns that are consecutive in the vertical direction and arranged between the drain select line and the source select line may function as the plurality of word lines WL1 to WLn in FIG. 2.

The channel structure CH extends through the first gate stack ST1 and the second gate stack ST2 in the vertical direction. The channel structure CH may be formed in a channel hole. The channel structure CH includes a core insulating layer 123 within a center region; a doped semiconductor layer 125 located at a lower end of the core insulating layer 123; a channel layer 121 surrounding a sidewall of the core insulating layer 123, the doped semiconductor layer 125, and an upper surface of the core insulating layer 123; and a memory layer 119 surrounding an outer wall of the channel layer 121. The channel layer 121 functions as a channel region of a corresponding cell string. The channel layer 121 may include a semiconductor material. The memory layer 119 includes a tunnel insulation layer (not shown) surrounding the outer wall of the channel layer 121, a data storage layer (not shown) surrounding an outer wall of the tunnel insulation layer, and a blocking insulation layer (not shown) surrounding an outer wall of the data storage layer.

The lower wiring 141 is arranged under the second gate stack ST2, near a lowermost surface of the second gate stack ST2. The lower wiring 141 may be a bit line. The lower wiring 141 is coupled to the channel structure CH via contacts 139 that extend through an insulating layer 135. The lower wiring 141 is spaced apart from the substrate 201 by a first insulating structure 151 and a second insulating structure 211.

The upper structure T includes a first dummy stack D_ST1 and a second dummy stack D_ST2 stacked in the vertical direction within a peripheral circuit region PR adjacent to or separated from the cell region CR, a first wiring 115, 137 extending vertically through the first dummy stack D_ST1 and the second dummy stack D_ST2, and a capacitor 233, 235, 237 arranged on (top of) the first dummy stack D_ST1 and coupled to the first wiring 115, 137.

The second dummy stack D_ST2 is arranged at the bottom of or below the first dummy stack D_ST1. The first dummy stack D_ST1 has a structure in which interlayer insulating layers 111 and sacrificial interlayer insulating layers 113 are alternately stacked. The second dummy stack D_ST2 has a structure in which interlayer insulating layers 111’ and sacrificial interlayer insulating layers 113’ are alternately stacked. The first wiring 115, 137 for the capacitor includes a first conductive layer 115 and a second conductive layer 137. Plug patterns include the first conductive layer 115 electrically coupled to the second conductive layer 137. At a region or border where the first conductive layer 115 contacts the second conductive layer 137, a width of the first conductive layer 115 is greater than the width of the second conductive layer 137. The second conductive layer 137 is electrically coupled to the lower wiring 141, and the lower wiring 141 in the peripheral circuit region PR is physically and electrically separated from the lower wiring 141 in the cell region CR.

The capacitor 233, 235, 237 arranged on the first dummy stack D_ST1 includes a first electrode 233, a dielectric layer 235, and a second electrode 237 that are consecutively stacked. The first electrode 233 is physically and electrically coupled to an end of the first conductive layer 115, and the second electrode 237 is physically and electrically coupled to a second wiring 243 coupled to the capacitor. The first electrode 233 is formed at the same vertical level as the source layer 231 within the cell region CR and may include the same material as the source layer 231.

An insulating layer 239 covering the top of the first gate stack ST1 and the first dummy stack D_ST1 is arranged on the upper structure T. At least one contact 241 extends through the insulating layer 239 and is coupled to the source layer 231. The second wiring 243 extends through the insulating layer 239 and is coupled to the second electrode 237 of the capacitor.

The first connecting structure 1st_CS includes the first insulating structure 151 and first connecting structures 143, 145, 147, 149, 153, and 155 formed within the first insulating structure 151. The first connecting structures 143, 145, 147, 149, 153, and 155 include various conductive patterns. The first insulating structure 151 includes two or more insulating layers 151A to 151D stacked between the bit line BL and the second insulating structure 211.

The source layer 231, a capacitor 233, 235, 237, contacts 241 for a source line, and an upper wiring 243 are arranged on (top of) the upper structure T. The source layer 231 is formed to electrically and physically contact the channel layers 121 of the channel structure CH protruding from the first gate stack ST1. The source layer 231 and the first gate stack ST1 are covered by an insulating layer 239, and the contact 241 for a source line extends through the insulating layer 233 and is coupled to the source layer 231.

The lower structure U includes a Complementary Metal-Oxide Semiconductor (CMOS) circuit including a plurality of transistors 200 formed on a substrate SUB, and a second connecting structure 2nd_CS formed on the CMOS circuit. An isolation layer 203 is arranged within the substrate SUB, and the isolation layer 203 isolates the junctions of the plurality of transistors 200 from each other.

The second connecting structure 2nd_CS includes the second insulating structure 211 formed on the substrate SUB and second connecting structures 213, 215, 217, 219, 221, and 223 formed within the second insulating structure 211. Each of the second connecting structures 213, 215, 217, 219, 221, and 223 are enclosed within the second insulating structure 211. The second insulating structure 211 may include two or more insulating layers 211A to 211D stacked consecutively.

The upper structure T is bonded to the lower structure U using a bonding process. For example, exposed conductive patterns 155 of the first connecting structure 1st_CS of the upper structure T are bonded to exposed conductive patterns 223 of the second connecting structure 2nd_CS of the lower structure U. The conductive patterns 155 and the conductive patterns 223 may be referred to as bonding metals.

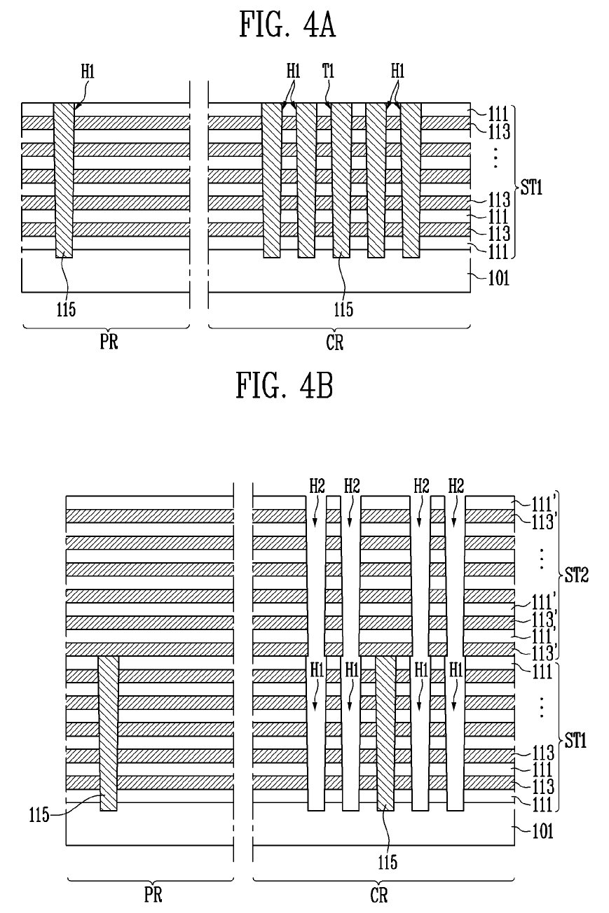

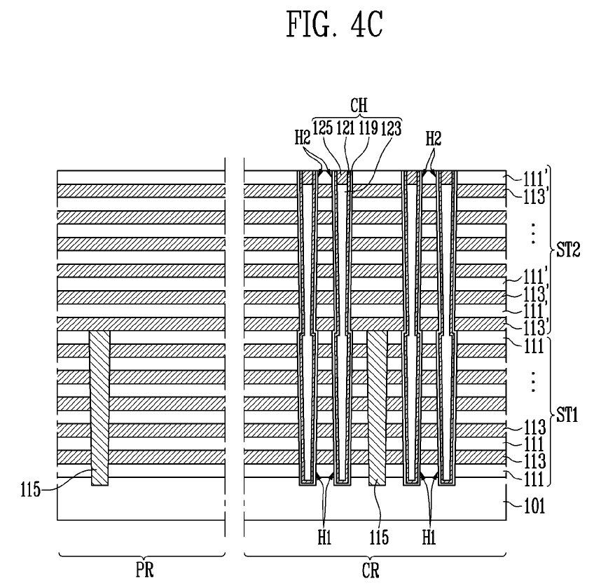

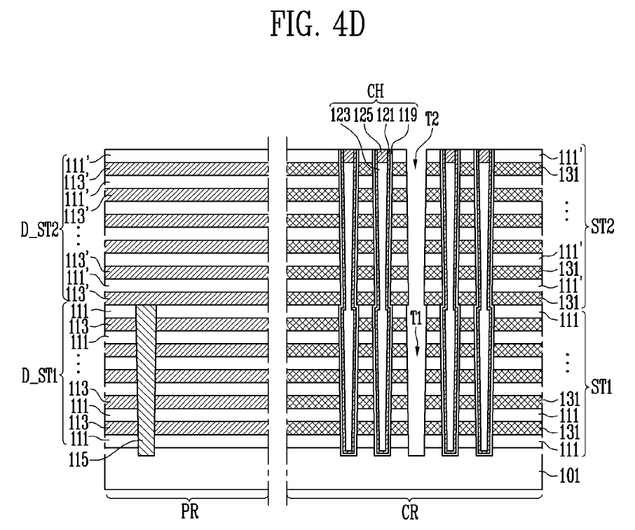

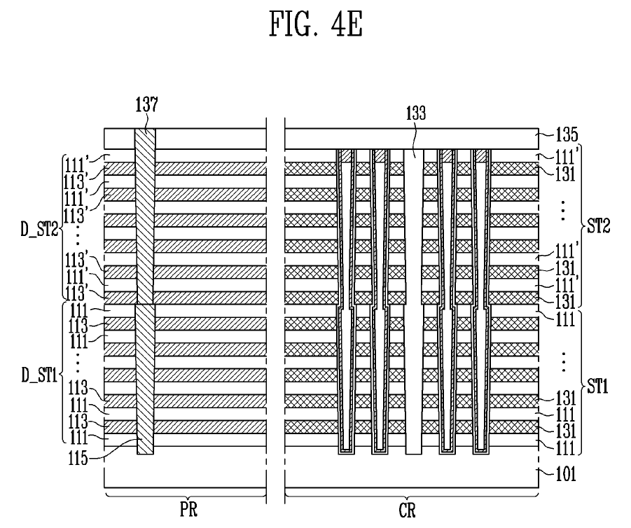

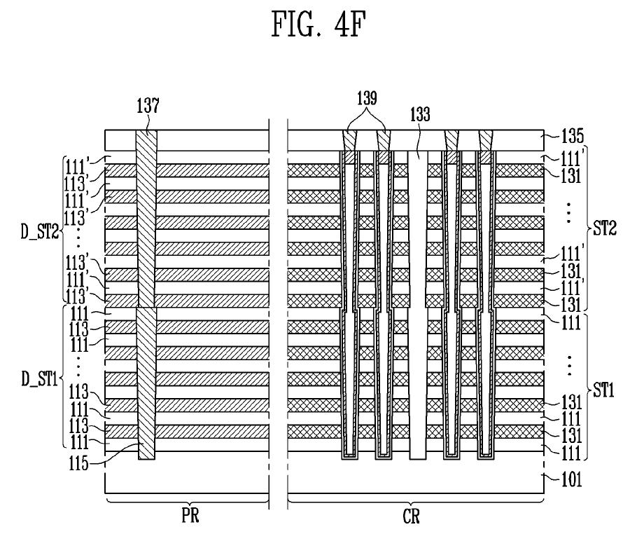

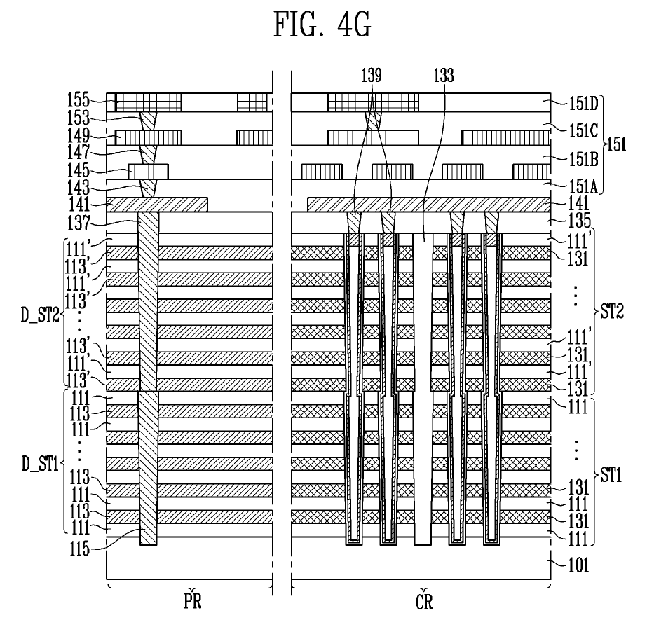

FIGS. 4A-4g, 5, 6, and 7A-7C are cross-sectional views of a semiconductor memory device formed utilizing a method of manufacturing a semiconductor memory device according to an embodiment of the present disclosure.

FIGS. 4A-4G are cross-sectional views of a semiconductor memory device formed utilizing a method of forming a memory cell array, a first wiring array, and first connecting structures on a first substrate.

Referring to FIG. 4A, interlayer insulating layers 111 are alternatively stacked with sacrificial interlayer insulating layers 113 on a first substrate 101 to form a first gate stack ST1.

The first substrate 101 includes the cell region CR and the peripheral circuit region PR. A capacitor is formed in the peripheral circuit region PR, and the channel structures are formed in the cell region CR.

The first substrate 101 may include a material having a different etch rate from the interlayer insulating layers 111 and the sacrificial interlayer insulating layers 113. For example, the substrate 101 may include silicon.

In an embodiment, the interlayer insulating layers 111 include an insulating material as described with reference to FIG. 3. The sacrificial interlayer insulating layers 113 include a material having a different etch rate from the interlayer insulating layers 111. For example, the interlayer insulating 111 may include a silicon oxide and the sacrificial interlayer insulating layers 113 may include a silicon nitride. The drawings illustrate an embodiment in which the interlayer insulating layers 111 include insulating material and the sacrificial interlayer insulating layers 113 are sacrificial layers, although the present disclosure is not limited to this example. The properties of the interlayer insulating layers 111 and the sacrificial interlayer insulating layers 113 may vary. For example, the interlayer insulating layers 111 may include an insulating material as described with reference to FIG. 3, and the sacrificial interlayer insulating layers 113, when replaced with the conductive patterns 131, may include a conductive material as described with reference to FIG. 3.

An etch process may be performed to form a plurality of first holes H1 extending through the first gate stack ST1. For example, the first holes H1 extending through the first gate stack ST1 in the peripheral circuit region PR are holes in which a first wiring for the capacitor is formed, and the first holes H1 extending through the first gate stack ST1 in the cell region CR are holes in which channel structures are formed.

During the etching process, a first trench T1 extending through the first gate stack ST1 is formed. The first trench T1 extends through the first gate stack ST1 in the cell region CR and extends in a horizontal direction with respect to the first substrate 101.

The first holes H1 extend through the first gate stack ST1 and extend partially into the first substrate 101.

Each of the first holes H1 is filled with the first conductive layer 115. The first conductive layer 115 may include an anti-diffusion layer and a conductive layer. For example, the anti-diffusion layer may include titanium nitride (TiN) and the conductive layer may include a low resistivity material such as tungsten (W). The anti-diffusion layer may surround the surface of the conductive layer.

Referring to FIG. 4B, a second gate stack ST2 is formed on the first gate stack ST1 and the first conductive layer 115. The second gate stack ST2 is formed by alternately stacking sacrificial interlayer insulating layers 113’ with interlayer insulating layers 111’. For example, the materials of the sacrificial interlayer insulating layers 113’ may be the same as the materials for the sacrificial interlayer insulating layers 113 of the first gate stack ST1, and the materials of the interlayer insulating layers 111’ may be the same as the materials for the interlayer insulating layers 111 of the first gate stack ST1.

An etching process is performed to to form second holes H2 extending through the second gate stack ST2 within the cell region CR, through which second holes H2 the first conductive layers 115 in FIG. 4A are exposed.

The first conductive layer within the first holes H1 is removed.

Referring to FIG. 4C, the channel structure CH is formed within the first holes H1 and the second holes H2 in the cell region CR.

For example, the memory layer 119, the channel layer 121, the core insulating layer 123, and the doped semiconductor layer 125 are formed inside the first holes H1 and the second holes H2.

In an embodiment, the memory layer 119 in the form of a liner is formed along the inner sidewalls of the gate stacks ST1 and ST2 adjacent to the first holes H1 and the second holes H2. The memory layer 119 includes a blocking insulation layer, a data storage layer, and a tunnel insulation layer consecutively formed along the inner sidewalls of the gate stacks ST1 and ST2 adjacent to the first holes H1 and the second holes H2.

The channel layers 121 are formed on the surfaces of the memory layer 119 to form the channel structures CH. The channel layer 121 may include undoped polysilicon.

In an embodiment, the channel layer 121 may be formed as a liner, and the center regions of the first holes H1 and the second holes H2 are not filled with the channel layer 121. When the channel layer 121 is formed as a liner, a process of forming the channel structure CH includes a process of filling the center regions of the first holes H1 and the second holes H2 with the core insulating layer 123 on the surface of the channel layer 121, and a process of etching an upper end of the core insulating layer 123 to form a recess region in the center region, and filling the recess region with the doped semiconductor layer 125. The core insulating layer 123 may include an oxide, and the doped semiconductor layer 125 may include conductive dopants. The conductive dopants may include n-type dopants for junctions. The conductive dopants may include counter-doped p-type dopants.

Referring to FIG. 4D, the second gate stack ST2 within the cell region CR is etched to form a second trench T2 to expose the first conductive layer 115 of FIG. 4C within the first trench T1. The second trench T2 extends in the same direction as the first trench T1. The first conductive layer in the exposed first trench T1 is removed. The first trench T1 and the second trench T2 may be referred to as slits T1, T2.

The sacrificial interlayer insulating layers 113 of FIG. 4C and the sacrificial interlayer insulating layers 113’ of FIG. 4C within the cell region CR exposed through the slit T1 and T2 are removed to form horizontal spaces, and the conductive patterns 131 are formed within each of the horizontal spaces from which the sacrificial interlayer insulating layers 113 of FIG. 4C and the sacrificial interlayer insulating layers 113’ of FIG. 4C were removed. The conductive patterns 131 may function as at least one drain select line, a plurality of word lines, and at least one source select line. The conductive patterns 131 surround the sidewalls of the channel structures CH.

The first gate stack ST1 includes the interlayer insulating layers 111 alternately stacked with the conductive layers 131, and the second gate stack ST2 includes the interlayer insulating layers 111’ alternately stacked with the conductive patterns 131. Accordingly, the channel structures CH extend through the gate stacks ST1 and ST2, and the slit T1, T2 extends through the gate stacks ST1 and ST2.

During the removal process of the sacrificial interlayer insulating layers 113 in FIG. 4C and the sacrificial interlayer insulating layers 113’ in FIG. 4C exposed through the slit T1, T2, an etch amount, an etch time, and so forth during the etch process may be adjusted to retain the sacrificial interlayer insulating layers 113 and the sacrificial interlayer insulating layers 113’ within the peripheral circuit region PR. The first gate stack including the interlayer insulating layers 111 alternately stacked with the sacrificial interlayer insulating layers 113 may be referred to as the first dummy stack D_ST1, and the second gate stack including the sacrificial interlayer insulating layers 113’ alternately stacked with the interlayer insulating layers 111’ may be referred to as the second dummy stack D_ST2.

Referring to FIG. 4E, the slit T1, T2 in FIG. 4D is filled with an insulating material to form the insulating pattern 133. The insulating layer 135 is formed on the second gate stack ST2 and the second dummy stack D_ST2. The insulating layer 135 and the second dummy stack D_ST2 within the peripheral circuit region PR are etched to form a hole through which the first conductive layer 115 is exposed, and the hole is filled with a conductive material to form the second conductive layer 137 that is electrically and physically coupled to the first conductive layer 115. The second conductive layer 137 may include an anti-diffusion layer and a conductive layer. For example, the anti-diffusion layer may include titanium nitride (TiN) and the conductive layer may include a low resistivity material such as tungsten (W). The anti-diffusion layer may surround the surface of the conductive layer. The first conductive layer 115 and the second conductive layer 137 may be referred to as a first wiring for the capacitor.

Referring to FIG. 4F, the insulating layer 135 within the cell region CR is etched to form contact holes that extend to the upper end of the channel structure CH, and the contact holes are filled with a conductive material to form the contacts 139 that electrically and physically connect to the upper end of the channel structure CH.

In an embodiment, the process of forming the contacts 139 may be performed in conjunction with the process of forming the second conductive layer 137 of FIG. 4E.

Referring to FIG. 4G, the lower wiring 141 is formed on the insulating layer 135 of the cell region CR and the peripheral circuit region PR. The lower wiring 141 within the cell region CR is a bit line coupled to the contacts 139 in an embodiment. The lower wiring 141 formed on the insulating layer 135 within the peripheral circuit region PR is electrically and physically coupled to the second conductive layer 137. The first insulating structure 151 is formed to cover the lower wiring 141. The first insulating structure 151 includes two or more insulating layers 151A to 151D. The first connecting structures 145, 149, and 155 are surrounded by the first insulating structure 151, and the first connecting structures 145, 149, and 155 are electrically coupled via contacts (e.g., 143, 147, and 153).

The first connecting structures 145, 149, and 155 include a first bonding metal 155 that includes a surface exposed outside the first insulating structure 151.

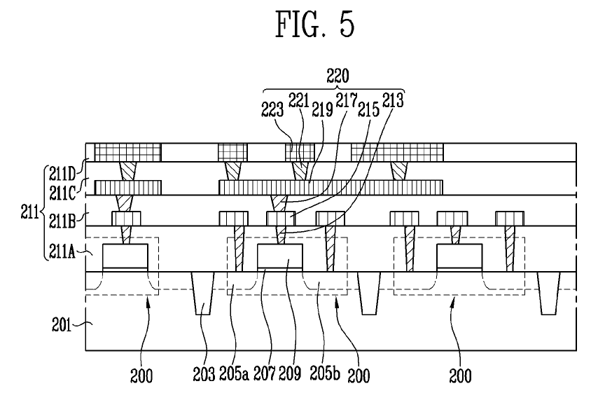

FIG. 5 is a cross-sectional view of a CMOS circuit and second connecting structures on a second substrate.

Referring to FIG. 5, the plurality of transistors 200 of a complementary metal oxide semiconductor (CMOS) circuit are formed on a second substrate 201.

The second substrate 201 may be a bulk silicon substrate, a silicon-on-insulator substrate, a germanium substrate, a germanium-on-insulator substrate, a silicon-germanium substrate, or an epitaxial layer formed via a selective epitaxial growth method.

Each of the transistors 200 are formed within an active region of the second substrate 201 that is divided by the isolation layers 203. Each of the transistors 200 includes a gate insulating layer 207 and a gate electrode 209 stacked within the corresponding active region, and junctions 205a and 205b formed within the active region on the sides of the gate electrode 209. The junctions 205a and 205b include conductive dopants for each corresponding transistor. The junctions 205a and 205b may include at least one of n-type dopants and p-type dopants.

In an embodiment, after the plurality of transistors 200 are formed, second connecting structures 220 coupled to the transistors 200 of the CMOS circuit are formed, and the second insulating structure 211 covering the second connecting structures 220 and the transistors 200 is formed.

The second insulating structure 211 includes two or more insulating layers 211A to 211D. The connecting structures 220 are surrounded by the second insulating structure 211. Each of the second connecting structures 220 includes a plurality of conductive patterns 213, 215, 217, 219, 221, and 223. The second insulating structure 211 and the second connecting structures 220 may vary and are not limited to the example shown in FIG. 5.

The conductive patterns 213, 215, 217, 219, 221, and 223 included in each of the second connecting structures 220 includes a second bonding metal 223 that includes an exposed surface outside the second insulating structure 211.

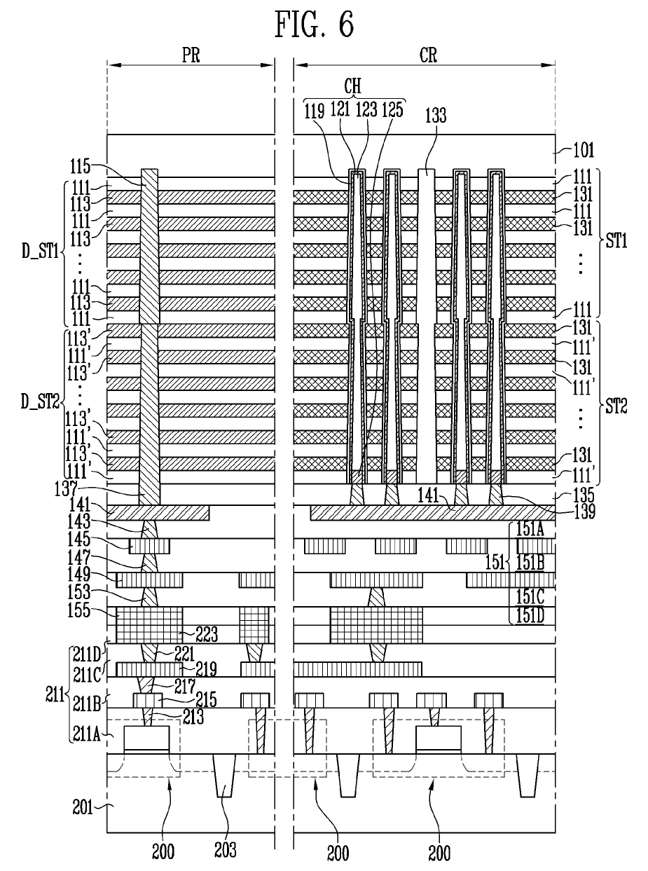

FIG. 6 is a cross-sectional view of a first connecting structure bonded to a second connecting structure.

Referring to FIG. 6, the first substrate 101 and the second substrate 201 are aligned such that the first bonding metal 155 on the first substrate 101 contacts the second bonding metal 223 on the second substrate 201. The first bonding metal 155 and the second bonding metal 223 may include various metals, for example, copper.

The first bonding metal 155 is bonded to the second bonding metal 223. Heat may be applied to the first bonding metal 155 and the second bonding metal 223, and the first bonding metal 155 and the second bonding metal 223 may be cured. The present disclosure is not limited to this example, and various processes may be employed to connect the first bonding metal 155 to the second bonding metal 223.

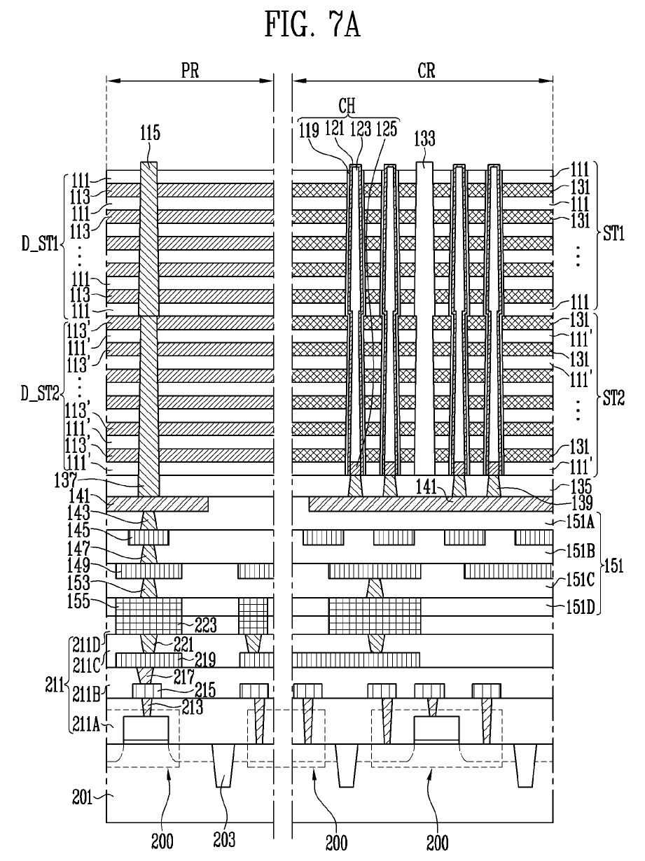

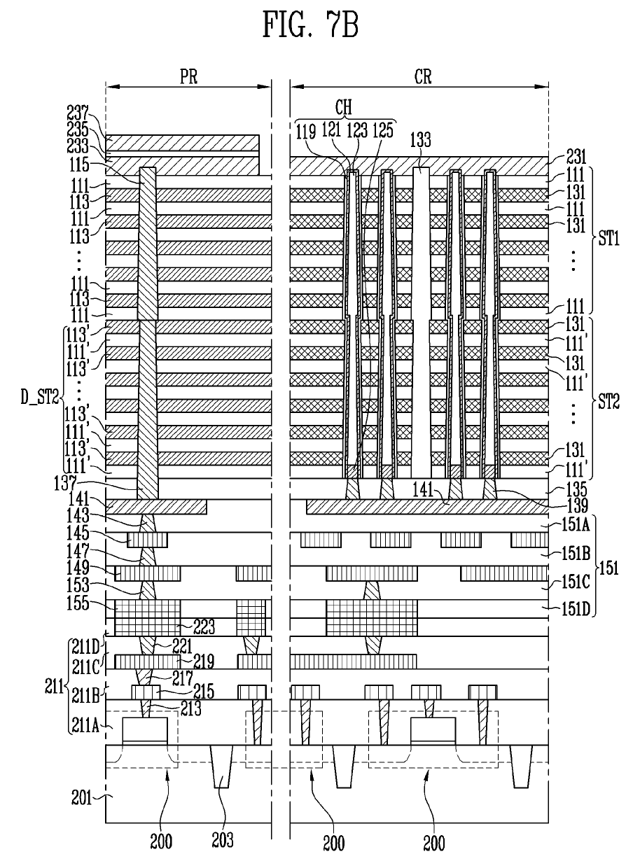

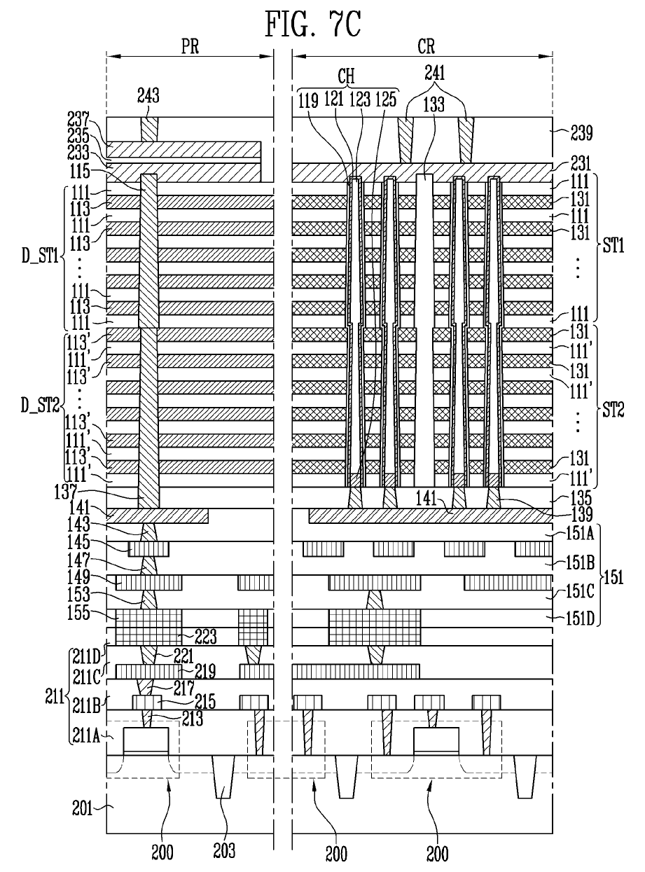

FIGS. 7A-7C are cross-sectional views of a source line structure coupled to a plurality of channel structures on the first gate stack ST1 and a capacitor structure on the first dummy stack D_ST1.

Referring to FIG. 7A, the first substrate 101 as shown in FIG. 6 is removed. As a result, the memory layer 119 and the channel layer 121 protrude from an uppermost surface of the first gate stack ST1, and the first conductive layer 115 protrudes from an uppermost surface of the first dummy stack D_ST1.

An etching process is performed to etch the memory layer 119 protruding from the uppermost surface of the first gate stack ST1 to expose the channel layer 121.

An ion implantation process may be performed to inject dopants into the channel layer 121 to form a junction region that functions as a channel of a source select transistor.

Referring to FIG. 7B, a conductive layer is formed to cover the uppermost surface of the first gate stack ST1 and the exposed surfaces of the channel layers 121 and to cover the uppermost surface of the first dummy stack D_ST1 and the exposed surface of the first conductive layers 115. A patterning process is performed to physically separate the conductive layer formed on the first gate stack ST1 from the conductive layer formed on the first dummy stack D_ST1. The conductive layer formed on the first gate stack ST1 is the source layer 231, and the conductive layer formed on the first dummy stack D_ST1 is the first electrode 233 of the capacitor. Accordingly, the source layer 231 is electrically and physically coupled to the channel layers 121 of the plurality of channel structures CH, and the first electrode 233 of the capacitor is electrically and physically coupled to the first conductive layer 115.

In an embodiment, the source layer 231 and the first electrode 233 of the capacitor may include a doped polysilicon layer.

The dielectric layer 235 having a high permittivity and the second electrode 237 of the capacitor are consecutively stacked on the first electrode 233 of the capacitor to form the capacitor 233, 235, 237. The dielectric layer 235 may include an oxide layer, and the second electrode 237 of the capacitor may include a doped polysilicon layer.

Referring to FIG. 7C, the insulating layer 239 covering the source layer 231 and the capacitor structure 233, 235, 237 is formed, and openings are formed by etching the insulating layer 239 to expose the source layer 231 and the second electrode 237 of the capacitor. The openings are filled with a conductive material to form the contacts 241 for the source line connecting to the source layer 231 and an upper wiring 243 coupled to the second electrode 237 of the capacitor.

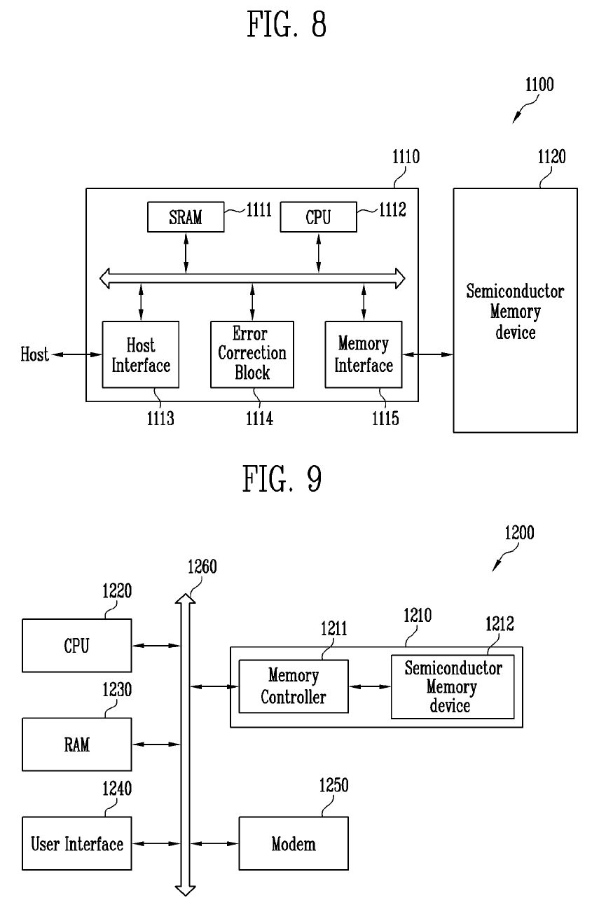

FIG. 8 is a block diagram illustrating a configuration of a memory system 1100 according to an embodiment of the present disclosure.

Referring to FIG. 8, the memory system 1100 includes a semiconductor memory device 1120 and a memory controller 1110.

The semiconductor memory device 1120 may be a multi-chip package that includes a plurality of flash memory chips. The semiconductor memory device 1120 includes the semiconductor memory device as described with reference to FIGS. 1-3.

The memory controller 1110 is configured to control the semiconductor memory device 1120 and includes static random access memory (SRAM) 1111, a central processing unit (CPU) 1112, a host interface 1113, an error correction block 1114, and a memory interface 1115. The SRAM 1111 is a working memory of the CPU 1112, the CPU 1112 performs overall control for data exchange for the memory controller 1110, and the host interface 1113 includes a data exchange protocol for a host coupled to the memory system 1100. The error correction block 1114 detects and corrects an error included in data read from the semiconductor memory device 1120, and the memory interface 1115 interfaces with the semiconductor memory device 1120. The memory controller 1110 may include read only memory (ROM) that stores code data that interface with the host.

The memory system 1100 may be a memory card or a solid state disk (SSD) into which the semiconductor memory device 1120 and the memory controller 1110 are integrated. For example, when the memory system 1100 is an SSD, the memory controller 1110 communicates with an external device, such as a host, using one of the interface protocols including Universal Serial Bus (USB), MultiMedia Card (MMC), Peripheral Component Interconnection-Express (PCI-E), Serial Advanced Technology Attachment (SATA), Parallel Advanced Technology Attachment (PATA), Small Computer System Interface (SCSI), Enhanced Small Disk Interface (ESDI), and Integrated Drive Electronics (IDE).

FIG. 9 is a block diagram illustrating a configuration of a computing system 1200 according to an embodiment of the present disclosure.

Referring to FIG. 9, the computing system 1200 includes a CPU 1220, random access memory (RAM) 1230, a user interface 1240, a modem 1250, and a memory system 1210 that are electrically coupled to a system bus 1260. When the computing system 1200 is a mobile or portable device, a battery that supplies an operating voltage to the computing system 1200 is included. An application chipset, an image processor, a mobile DRAM, and the like may be included. The memory system 1210 includes a memory controller 1211 and a semiconductor memory device 1212.

According to the present disclosure, an electrode for a capacitor may be formed within a peripheral circuit region adjacent to a cell region during a process of forming a source line layer coupled to an end of a channel structure within the cell region, thereby facilitating a manufacturing process.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor memory device comprising:
a gate stack formed within a cell region of the semiconductor memory device;
a dummy stack formed within a peripheral circuit region of the semiconductor memory device and separated from the cell region;
a source layer formed on the gate stack;
a capacitor including a first electrode, a dielectric layer, and a second electrode formed on the dummy stack; and
a plurality of channel structures extending through the dummy stack and protruding into the source layer;
wherein the source layer is formed at a same level as the first electrode.

2. The semiconductor memory device of claim 1, wherein the source layer and the first electrode include a same material.

3. The semiconductor memory device of claim 2, wherein the source layer and the first electrode comprise a doped polysilicon layer.

4. The semiconductor memory device of claim 1, further comprising a third electrode extending through the dummy stack and coupled to the first electrode of the capacitor.

5. The semiconductor memory device of claim 1, further comprising:
a fourth electrode coupled to the second electrode of the capacitor; and
a contact coupled to the source layer.

6. The semiconductor memory device of claim 1, further comprising a bit line arranged near the gate stack and coupled to a first end of each of the plurality of channel structures.

7. The semiconductor memory device of claim 6, further comprising:
a first connecting structure including a first bonding metal coupled to the bit line and including an exposed surface;
a second connecting structure including a second bonding metal in contact with the first bonding metal of the first connecting structure; and
a Complementary Metal-Oxide Semiconductor circuit structure coupled to the second connecting structure and including a plurality of transistors.

8. A semiconductor memory device comprising:
a gate stack formed within a cell region of the semiconductor memory device;
a dummy stack formed within a peripheral circuit region of the semiconductor memory device and separated from the cell region;
a source layer formed on the gate stack;
a capacitor including a first electrode, a dielectric layer, and a second electrode formed on the dummy stack;
a plurality of channel structures extending through the dummy stack and protruding into the source layer;
a first connecting structure including a first bonding metal having a surface near the gate stack;
a second connecting structure including a second bonding metal in contact with the first bonding metal of the first connecting structure; and
a Complementary Metal-Oxide Semiconductor (CMOS) circuit structure coupled to the second connecting structure and including a plurality of transistors.

9. The semiconductor memory device of claim 8, wherein the source layer is formed at a same level as the first electrode.

10. The semiconductor memory device of claim 8, wherein the source layer and the first electrode include a same material.

11. The semiconductor memory device of claim 10, wherein the source layer and the first electrode comprise a doped polysilicon layer.

12. The semiconductor memory device of claim 8, further comprising a third electrode extending through the dummy stack and coupled to the first electrode of the capacitor.

13. The semiconductor memory device of claim 8, further comprising:
a fourth electrode coupled to the second electrode of the capacitor; and
a contact coupled to the source layer.

14. The semiconductor memory device of claim 8, further comprising a bit line arranged near the gate stack and coupled to a first end of each of the plurality of channel structures,
wherein the bit line is coupled to the first connecting structure.

15. A method of manufacturing a semiconductor memory device, the method comprising:
forming a stack including interlayer insulating layers alternately stacked with sacrificial layers in a first direction on a first substrate including a cell region and a peripheral circuit region, and a plurality of channel structures extending through the stack within the cell region;
forming a gate stack including the interlayer insulating layers alternately stacked with conductive layers within the cell region by replacing the sacrificial layers within the cell region with conductive layers, and forming a dummy stack by alternately stacking the interlayer insulating layers with the sacrificial layers within the peripheral circuit region;
forming a bit line coupled to each of the plurality of channel structures;
removing the first substrate to expose the plurality of channel structures;
forming a conductive layer on the gate stack and the dummy stack exposed by removing the first substrate, and forming a source layer connected to the plurality of channel structures on the gate stack and a first electrode on the dummy stack by patterning the conductive layer; and
forming a capacitor by consecutively forming a dielectric layer and a second electrode on the first electrode.

16. The method of claim 15, wherein the source layer and the first electrode comprise a doped polysilicon layer.

17. The method of claim 15, further comprising forming a third electrode extending through the dummy stack and coupled to the capacitor.

18. The method of claim 15, further comprising:
forming a first conductive connecting structure on the bit line;
forming a complementary metal oxide semiconductor (CMOS) circuit on the second substrate;
forming a second conductive connecting structure coupled to the CMOS circuit on the second substrate; and
bonding a first bonding metal of the first connecting structure to a second bonding metal of the second connecting structure to couple the first connecting structure to the second connecting structure.

19. The method of claim 15, further comprising, performing ion implantation to implant a dopant into a channel layer of each of the plurality of channel structures.

20. The method of claim 15, further comprising:
forming an insulating layer covering the capacitor and the source layer; and
forming a wiring extending through the insulating layer and coupled to the capacitor, and a contact coupled to the source layer.
